(19) United States
(12) Patent Application Publication
(10) Pub. No.: US 2022/0029266 A1
(43) Pub. Date: Jan. 27, 2022

(54) QUANTUM CHIP PREPARATION METHOD, APPARATUS, AND DEVICE AND QUANTUM CHIP

(71) Applicant: ALIBABA GROUP HOLDING LIMITED, George Town (KY)

(72) Inventors: Wenlong YU, Hangzhou (CN); Hantao SUN, Hangzhou (CN); Tenghui WANG, Hangzhou (CN)

(21) Appl. No.: 17/381,758

(22) Filed: Jul. 21, 2021

(30) Foreign Application Priority Data
Jul. 22, 2020 (CN) 202010713145.1

(51) Int. Cl. H01P 3/12; H01L 21/66; H01L 39/22; H01L 39/02; H01B 12/04

(52) U.S. Cl. CPC H01P 3/12; H01L 22/14; H01B 12/04; H01L 39/025; H01L 39/223

(57) ABSTRACT

Methods, apparatuses, and devices for quantum chip preparation include acquiring a coplanar waveguide in a quantum chip; and establishing a connecting bridge on the coplanar waveguide using a bonding machine, wherein the connecting bridge is configured to connect a first reference ground and a second reference ground located on two sides of the coplanar waveguide to change the chip electromagnetic resonance frequency. A quantum chip includes a transmission line configured for signal transmission; and a resonant cavity coupled to the transmission line and configured to regulate an operating state of qubits on the quantum chip, wherein the transmission line and the resonant cavity are both composed of a coplanar waveguide, the coplanar waveguide is provided with a connecting bridge, and the connecting bridge is configured to connect a first reference ground and a second reference ground on two sides of the coplanar waveguide to change the chip electromagnetic resonance frequency.

### CROSS-REFERENCE TO RELATED APPLICATIONS

The present disclosure claims benefits of and priority to Chinese patent application No. 202010713145.1, filed on Jul. 22, 2020, the content of which is incorporated herein by reference in its entirety.

### TECHNICAL FIELD

The present disclosure relates to the field of superconducting technologies, and in particular, to a quantum chip preparation method, apparatus, and device and a quantum chip.

### BACKGROUND

After a superconducting quantum chip is manufactured, it is necessary to perform a test operation on the superconducting quantum chip to ensure that the performance and functions of the prepared quantum chip can meet design requirements. However, when a superconducting quantum chip is tested, if the quantum chip has chip electromagnetic resonance, the existing chip electromagnetic resonance will seriously affect the normal operation of the quantum chip.

Therefore, there is an urgent need to eliminate or reduce the influence of the chip electromagnetic resonance on the quantum chip, so as to ensure or improve the stable and reliable operation of the quantum chip.

### SUMMARY

The embodiments of present disclosure provide methods, apparatuses, and devices for quantum chip preparation. In an aspect, a method for quantum chip preparation includes: acquiring a coplanar waveguide in a quantum chip; and establishing a connecting bridge on the coplanar waveguide using a bonding machine, wherein the connecting bridge is configured to connect a first reference ground and a second reference ground located on two sides of the coplanar waveguide to change the chip electromagnetic resonance frequency.

In another aspect, an apparatus for quantum chip preparation includes an acquisition module configured to acquire a coplanar waveguide in a quantum chip; and a preparation module configured to establish a connecting bridge on the coplanar waveguide using a bonding machine, wherein the connecting bridge is configured to connect a first reference ground and a second reference ground located on two sides of the coplanar waveguide to change the chip electromagnetic resonance frequency.

In yet another aspect, an apparatus for inductance element preparation is provided. The apparatus includes a memory configured to store a set of instructions and one or more processors communicatively coupled to the memory and configured to execute the set of instructions to cause the apparatus to perform: acquiring a coplanar waveguide in a quantum chip; and establishing a connecting bridge on the coplanar waveguide using a bonding machine, wherein the connecting bridge is configured to connect a first reference ground and a second reference ground located on two sides of the coplanar waveguide to change the chip electromagnetic resonance frequency.

In yet another aspect, a quantum chip is provided. The quantum chip is prepared by a method, the method including: acquiring a coplanar waveguide in a quantum chip; and establishing a connecting bridge on the coplanar waveguide using a bonding machine, wherein the connecting bridge is configured to connect a first reference ground and a second reference ground located on two sides of the coplanar waveguide to change the chip electromagnetic resonance frequency.

In yet another aspect, a quantum chip is provided. The quantum chip includes a transmission line configured for signal transmission; and a resonant cavity coupled to the transmission line and configured to regulate an operating state of qubits on the quantum chip, wherein the transmission line and the resonant cavity are both composed of a coplanar waveguide, the coplanar waveguide is provided with a connecting bridge, and the connecting bridge is configured to connect a first reference ground and a second reference ground on two sides of the coplanar waveguide to change the chip electromagnetic resonance frequency.

### BRIEF DESCRIPTION OF THE DRAWINGS

Embodiments and various aspects of present disclosure are illustrated in the following detailed description and the accompanying figures. Various features shown in the figures are not drawn to scale. To describe the technical solutions in the embodiments of the present disclosure more clearly, the accompanying drawings required for describing the embodiments are briefly introduced below. It is apparent that the accompanying drawings described in the following are merely some embodiments of the present disclosure, and those of ordinary skill in the art can still derive other drawings from these accompanying drawings without creative efforts.

FIG. 1 is a flowchart illustrating an example method for quantum chip preparation, consistent with some embodiments of the present disclosure.

FIG. 2 is a schematic diagram illustrating an example coplanar waveguide, consistent with some embodiments of the present disclosure.

FIG. 3A is a first schematic diagram illustrating an example coplanar waveguide and an example connecting bridge, consistent with some embodiments of the present disclosure.

FIG. 3B is a second schematic diagram illustrating the example coplanar waveguide and the example connecting bridge in FIG. 3A, consistent with some embodiments of the present disclosure.

FIG. 4 is a flowchart of an example method for acquiring a coplanar waveguide included in a quantum chip, consistent with some embodiments of the present disclosure.

FIG. 5 is a flowchart of an example method for establishing a connecting bridge on a coplanar waveguide by using a bonding machine, consistent with some embodiments of the present disclosure.

FIG. 6 is a flowchart of an example method for determining at least one key position for establishing a connecting bridge on a coplanar waveguide, consistent with some embodiments of the present disclosure.

FIG. 7 is a flowchart of an example method for quantum chip preparation, consistent with some embodiments of the present disclosure.

FIG. 8 is a flowchart of an example method for detecting whether a quantum chip has a chip electromagnetic resonance phenomenon, consistent with some embodiments of the present disclosure.

FIG. 9 is a schematic scenario diagram illustrating an example method for quantum chip preparation, consistent with some embodiments of the present disclosure.

FIG. 10 is a schematic structural diagram illustrating a quantum chip preparation apparatus, consistent with some embodiments of the present disclosure.

FIG. 11 is a schematic structural diagram illustrating a quantum chip preparation device, consistent with some embodiments of the present disclosure.

FIG. 12 is a schematic structural diagram illustrating an example quantum chip, consistent with some embodiments of the present disclosure.

### DETAILED DESCRIPTION

Reference can now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the disclosure as recited in the appended claims. Particular aspects of present disclosure are described in greater detail below. The terms and definitions provided herein control, if in conflict with terms and/or definitions incorporated by reference.

The terminology used in the embodiments of the present disclosure is for the purpose of describing particular embodiments only, and is not intended to limit the present disclosure. The singular forms “a,” “said,” and “the” used in the embodiments of the present disclosure and the appended claims are also intended to include plural forms, unless other meanings are clearly indicated in the context, and “multiple” generally includes at least two, but does not exclude the case of including at least one.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a component can include A or B, then, unless specifically stated otherwise or infeasible, the component can include A, or B, or A and B. As a second example, if it is stated that a component can include A, B, or C, then, unless specifically stated otherwise or infeasible, the component can include A, or B, or C, or A and B, or A and C, or B and C, or A and B and C.

Depending on the context, the words “in case of” and “if” as used herein can be interpreted as “at the time of” or “when” or “in response to determination” or “in response to detection.” Similarly, depending on the context, the phrase “if determined” or “if detected (a stated condition or event)” can be interpreted as “when determined” or “in response to determination” or “when detected (a stated condition or event)” or “response to detection (of a stated condition or event).”

It should be further noted that the terms “include,” “comprise,” or any other variations thereof are intended to cover non-exclusive inclusion, so that a commodity or system including a series of elements not only includes the elements, but also includes other elements not explicitly listed, or further includes elements inherent to the commodity or system. In the absence of more limitations, an element defined by “including a/an . . . ” does not exclude that the commodity or system including the element further has other identical elements. In addition, the sequence of steps in the following method embodiments is only an example, not a strict limitation.

Chip electromagnetic resonance, as used herein, can refer to additional non-designed electromagnetic resonances caused by a quantum chip and its surrounding environment when microwaves propagate on the chip. The microwaves in this disclosure can refer to electromagnetic waves with a frequency between 50 MHz and 20 GHz. The additional electromagnetic resonances can dissipate microwave energy, disrupt normal operation of the quantum chip, or affect the performance of the quantum chip.

Micro-nano processing and manufacturing technology, as used herein, can refer to the technology for designing, processing, assembling, integrating, and applying parts, components, or systems composed of these parts or components with dimensions of millimeters, micrometers, or nanometers.

Typically, after manufacturing a superconducting quantum chip, a test operation can be performed on the superconducting quantum chip to ensure that the performance and functions of the prepared quantum chip can meet design requirements. However, if the superconducting quantum chip has chip electromagnetic resonance when the test operation is performed on the superconducting quantum chip, the existing chip electromagnetic resonance can affect the normal operation of the superconducting quantum chip.

Some existing solutions are adopted to eliminate or reduce the influence of the chip electromagnetic resonance on the quantum chip, and to ensure or improve the stable and reliable operation of the quantum chip. A first existing solution is to eliminate the chip electromagnetic resonance of a superconducting quantum chip by changing a package structure of the chip. Specifically, the chip electromagnetic resonance of the quantum chip includes the electromagnetic resonance caused by the package structure and the chip electromagnetic resonance caused by a circuit layout structure of the quantum chip itself. Therefore, the additional electromagnetic resonance of the chip can be reduced or eliminated by changing the package structure of the quantum chip. However, the chip electromagnetic resonance can be affected by comprehensive factors such as chip design, manufacturing process, package structure, or test environment. Therefore, the first existing solution cannot effectively reduce or eliminate the chip electromagnetic resonance of the chip and can encounter difficulties in achieving expected results.

A second existing solution is to manufacture a superconducting wire connecting bridge on a quantum chip by the micro-nano processing and manufacturing technology, so as to reduce or eliminate the chip electromagnetic resonance of the chip through the established superconducting wire connecting bridge. However, due to the very small size corresponding to the micro-nano processing and manufacturing technology, when the connecting bridge is manufactured in a range of small sizes, not only many precision devices are required, but also the manufacturing process can have challenges of being cumbersome, complicated, time-consuming, or labor-intensive. Moreover, the excessive manufacturing processes cannot only reduce the performance of the quantum chip, but also reduce the yield of the quantum chip. The performance of the quantum chip can be further reduced due to limitations by the ultra-small size of the connecting bridge.

To solve the technical problems of the reduced performance of the quantum chip due to the chip electromagnetic resonance, this disclosure provides technical solutions including methods, apparatuses, and devices for quantum chip preparation, as well as quantum chips. In some embodiments, a coplanar waveguide included in a quantum chip can be acquired, and then a connecting bridge can be established on the coplanar waveguide by using a bonding machine. The connecting bridge can be configured to connect a first reference ground and a second reference ground located on two sides of the coplanar waveguide. The chip electromagnetic resonance of the quantum chip can be mainly affected by capacitance and inductance. By connecting the reference grounds located on two sides of the coplanar waveguide through the connecting bridge, the capacitance and inductance of the quantum chip can be changed effectively, thereby changing the chip electromagnetic resonance frequency of the quantum chip, and effectively eliminating or reducing the influence of the chip electromagnetic resonance on the quantum chip by building the connecting bridge on the planar waveguide. By doing so, the performance of the quantum chip can be improved, which can further increase the practicability of the method and beneficiary for market promotion and industrial application.

Some implementations of the present disclosure will be described in detail below with reference to the accompanying drawings. Provided that there is no conflict between the embodiments, the following embodiments and features in the embodiments can be combined with each other.

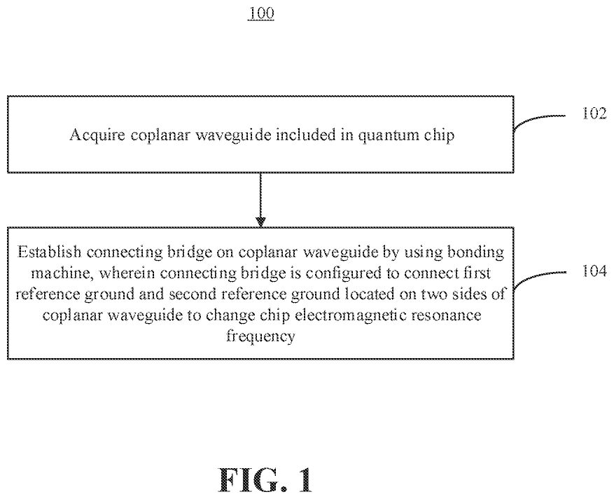

FIG. 1 is a flowchart illustrating an example method 100 for quantum chip preparation, consistent with some embodiments of the present disclosure. Method 100 can be executed by a quantum chip preparation device. It is understandable that the preparation device can be implemented as software or a combination of software and hardware.

With reference to FIG. 1, at step 102, a coplanar waveguide included in a quantum chip can be acquired. At step 104, a connecting bridge can be established on the coplanar waveguide by using a bonding machine. The connecting bridge can be configured to connect a first reference ground and a second reference ground on two sides of the coplanar waveguide to change the chip electromagnetic resonance frequency.

A coplanar waveguide in this disclosure can refer to a structure formed after a central conductor strip being manufactured on a surface (e.g., a single surface) of a dielectric substrate and conductor planes being manufactured closely adjacent to two sides of the central conductor strip. The coplanar waveguide can also be referred to as a coplanar microstrip transmission line.

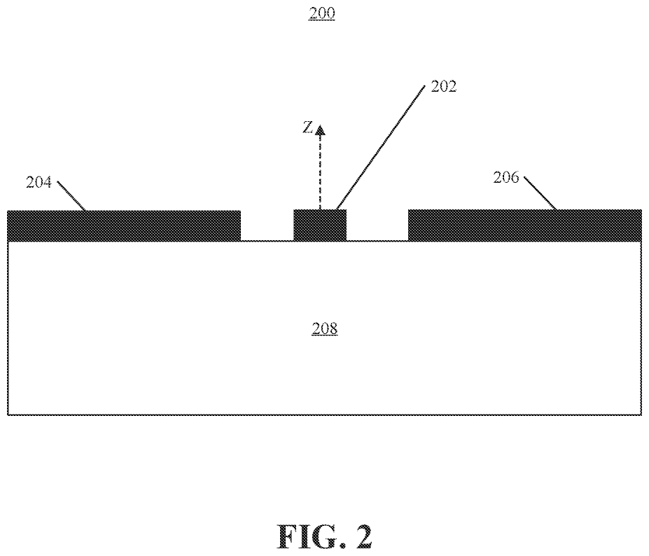

By way of example, FIG. 2 is a schematic diagram illustrating an example coplanar waveguide 200, consistent with some embodiments of the present disclosure. As shown in FIG. 2, coplanar waveguide 200 can include a central strip 202 located on a surface of dielectric substrate 208 in the middle and ground strips 204 and 206 located on two sides of central strip 202.

In some embodiments, a machine learning technique can be used to implement step 102. For example, a machine learning model can be pre-trained. The machine learning model can be used to recognize a coplanar waveguide included in a quantum chip. After a layout structure of the quantum chip is acquired, the layout structure of the quantum chip can be input to the machine learning model, so that the coplanar waveguide included in the quantum chip can be identified. In some embodiments, structural features of the coplanar waveguide can be acquired, and the coplanar waveguide included in the quantum chip can be identified through the structural features. It should be noted that those skilled in the art can also use other methods to identify the coplanar waveguide included in the quantum chip, as long as the accuracy and reliability of the acquisition of the coplanar waveguide can be ensured.

A bonding machine in this disclosure can refer to a device configured to realize a wire bonding process. Referring back to step 104 of FIG. 1, in some embodiments, after the coplanar waveguide is acquired, the bonding machine can be used to establish a connecting bridge on the coplanar waveguide. The connecting bridge can be configured to connect the first reference ground and the second reference ground on two sides of the coplanar waveguide. Because the chip electromagnetic resonance of the quantum chip can be mainly affected by the capacitance and inductance on the quantum chip, by connecting reference grounds (e.g., the first reference ground and the second reference ground) on two sides of the coplanar waveguide through the connecting bridge, the capacitance and inductance of the quantum chip can be changed effectively, thereby changing the chip electromagnetic resonance frequency of the quantum chip, and effectively eliminating or reducing the influence of the chip electromagnetic resonance on the quantum chip by building the connecting bridge on the planar waveguide. By doing so, the performance of the quantum chip can be improved, which can further increase the practicability of the method and beneficiary for market promotion and industrial application.

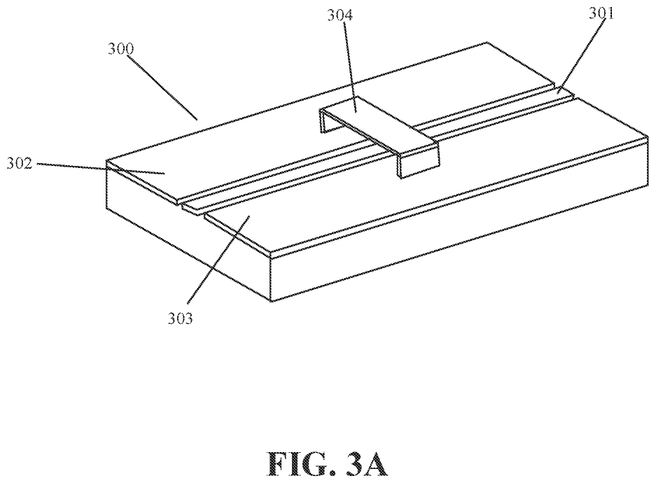

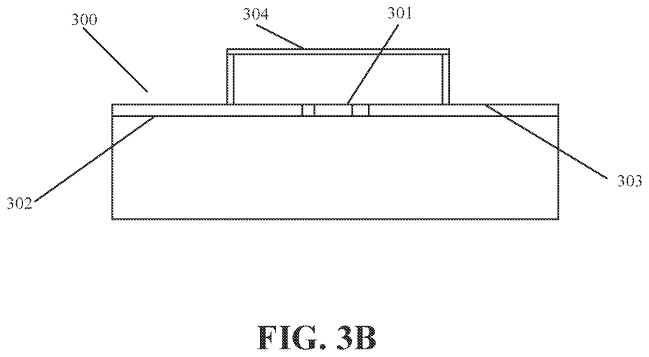

FIG. 3A is a first schematic diagram illustrating a coplanar waveguide 300 and a connecting bridge 304, consistent with some embodiments of the present disclosure. FIG. 3B is a second schematic diagram illustrating coplanar waveguide 300 and connecting bridge 304 in FIG. 3A, consistent with some embodiments of the present disclosure. As shown in FIG. 3A to FIG. 3B, coplanar waveguide 300 includes a central strip 301, a first reference ground 302 located on one side of central strip 301, and a second reference ground 303 located on the other side of central strip 301.

To reduce or avoid the influence of the chip electromagnetic resonance on the quantum chip, connecting bridge 304 can be arranged on coplanar waveguide 300. As shown in FIG. 3A to FIG. 3B, connecting bridge 304 has one end connected to first reference ground 302, and the other end connected to second reference ground 303. Connecting bridge 304 can change the chip electromagnetic resonance frequency of the quantum chip, thereby reducing the influence of the chip electromagnetic resonance on the quantum chip.

In some embodiments, the number of the connecting bridges can be one or more (not shown in FIGS. 3A-3B). When the number of the connecting bridges is at least one, a distance between two adjacent connecting bridges can be smaller than or equal to a preset value. The specific numerical range of the preset value is not limited in the present embodiment and can be set by those skilled in the art according to specific application requirements and design requirements. For example, the preset value can be 200 microns, 150 microns, 100 microns, or any microns. When the number of the connecting bridges is at least two, making the distance between two adjacent connecting bridges of the plurality of connecting bridges smaller than or equal to the preset value can further reduce the influence of the chip electromagnetic resonance on the quantum chip.

In some embodiments, when the number of the connecting bridges is more than one, density information of the connecting bridges can be greater than or equal to a preset density threshold. The preset density threshold can be determined based on space occupied by the quantum chip, the performance of the bonding machine, or the wire diameter. When the number of the connecting bridges is more than one, greater density information set for the connecting bridges can reduce the influence of the chip electromagnetic resonance on the quantum chip more effectively. It should be noted that with the continuous increase of the density information of the connecting bridge, the time cost and the degree of difficulty of manufacturing the connecting bridge can gradually increase. Therefore, in various applications, the manufacturing cost, the efficiency of the connecting bridge, and the influence of the chip electromagnetic resonance on the quantum chip can be comprehensively considered to configure the space occupied by the quantum chip, the performance of the bonding machine, or the wire diameter, thus facilitating determining the preset density threshold based on the configured space occupied by the quantum chip, the performance of the bonding machine, or the wire diameter. By doing so, control and adjustment operations of the density information of the connecting bridge can be improved.

In some embodiments, when the number of the connecting bridges is at least one, a pre-trained machine learning model can be used to determine at least one position for establishing the connecting bridge, and the connecting bridge can be established based on the determined at least one position. For example, when the machine learning model is configured to determine at least one location for establishing a connecting bridge, limiting information used for determining the connecting bridge can be acquired. The limiting information can include, for example, a distance limit value between the connecting bridges, a density limit value of the connecting bridges, or the like. Then, at least one position for establishing the connecting bridge on the coplanar waveguide can be determined based on the distance limit value between the connecting bridges and the density limit value of the connecting bridges. By doing so, the quality and efficiency of establishing the connecting bridge can be effectively ensured.

In some embodiments, when the number of the connecting bridges is more than one, at least one position for establishing the connecting bridge can be sequentially determined by using a pre-trained machine learning model, and the connecting bridge can be established based on the determined at least one position. For example, the machine learning model can be configured to determine a position for establishing a connecting bridge. After the coplanar waveguide of the quantum chip is acquired, a preset limiting condition for establishing the connecting bridge can be acquired. In some embodiments, the preset limiting condition can include at least one of a distance limit value between the connecting bridges, a density limit of the connecting bridges, quantity information of the connecting bridges, or any other limiting conditions. After the preset limiting condition for establishing the connecting bridge is acquired, the coplanar waveguide can be analyzed by using the preset limiting condition and the machine learning model, so that a first position for establishing the connecting bridge can be determined. After the first position is determined, a first connecting bridge can be established at the first position, so that a first intermediate structure corresponding to the quantum chip can be generated. Then, the first intermediate structure can be analyzed by using the machine learning model to determine a second position for establishing a connecting bridge on the first intermediate structure. After the second position is determined, a second connecting bridge can be established at the second position, so that a second intermediate structure corresponding to the quantum chip can be generated. Then, the second intermediate structure can be analyzed by using the machine learning model. The intermediate structure corresponding to the quantum chip can be repeatedly processed iteratively until a connecting bridge that can meet the preset limiting condition is established on the quantum chip.

In some embodiments, the wire used to manufacture the connecting bridge can be a superconducting wire. For example, the connecting bridge can be composed of a superconducting wire. By way of example, the superconducting wire can include an aluminum wire.

In some embodiments, to avoid the influence of the established connecting bridge on a transmission signal of the quantum chip, an arrangement direction of the connecting bridge can be perpendicular to a signal transmission direction of the coplanar waveguide.

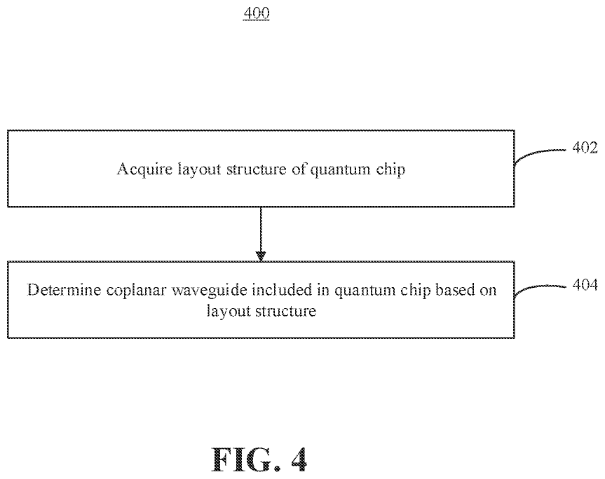

FIG. 4 is a flowchart of an example method 400 for acquiring a coplanar waveguide included in a quantum chip, consistent with some embodiments of the present disclosure. Method 400 can be implemented in accordance with specific application requirements and design requirements, which is not limited in the example embodiments of this disclosure. Method 400 can be executed by a quantum chip preparation device. It is understandable that the preparation device can be implemented as software or a combination of software and hardware.

With reference to FIG. 4, at step 402, a layout structure of a quantum chip can be acquired. At step 404, a coplanar waveguide included in the quantum chip can be determined based on the layout structure.

In some embodiments, after the quantum chip is acquired, the quantum chip can be analyzed to acquire the layout structure of the quantum chip at step 402. For example, the quantum chip can be analyzed by a preset layout recognition algorithm to acquire the layout structure of the quantum chip. After the layout structure is acquired, the layout structure can be analyzed to determine a coplanar waveguide included in the quantum chip at step 404. The number of coplanar waveguides can be one or more.

In some embodiments, at step 404, determining the coplanar waveguide included in the quantum chip based on the layout structure can include analyzing the layout structure by using a machine learning model to determine a coplanar waveguide included in the quantum chip. The machine learning model can be trained to be configured to determine a coplanar waveguide included in a quantum chip based on a layout structure.

In the technical solutions provided in this disclosure, the layout structure can be analyzed by the machine learning model to determine the coplanar waveguide included in the quantum chip. By doing so, not only the accuracy and reliability of the acquisition of the coplanar waveguide can be ensured, but also the quality and efficiency of the acquisition of the coplanar waveguide can be improved, thus further improving the stability and reliability of using method 400.

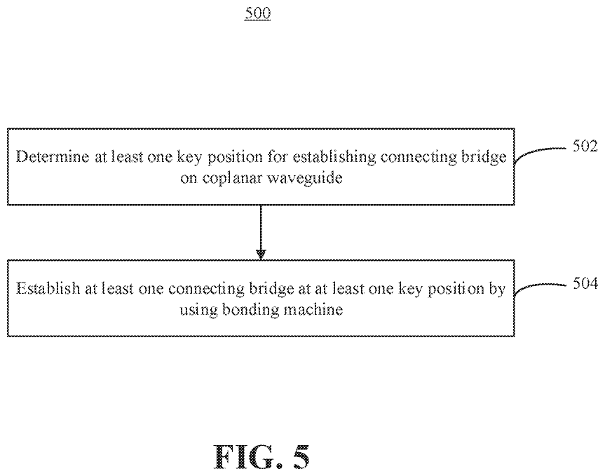

FIG. 5 is a flowchart of an example method 500 for establishing a connecting bridge on a coplanar waveguide by using a bonding machine, consistent with some embodiments of the present disclosure. Method 500 can be executed by a quantum chip preparation device. It is understandable that the preparation device can be implemented as software or a combination of software and hardware.

At step 502, at least one key position for establishing a connecting bridge can be determined on the coplanar waveguide. A key position, as used herein, can refer to the position on the coplanar waveguide where the electromagnetic field energy density is relatively large, the capacitance is relatively strong, or the inductance is relatively strong. The key position can have a relatively great impact on the chip electromagnetic resonance of the quantum chip. To reduce or avoid the influence of the chip electromagnetic resonance on the quantum chip, at least one key position for establishing the connecting bridge can be determined on the coplanar waveguide.

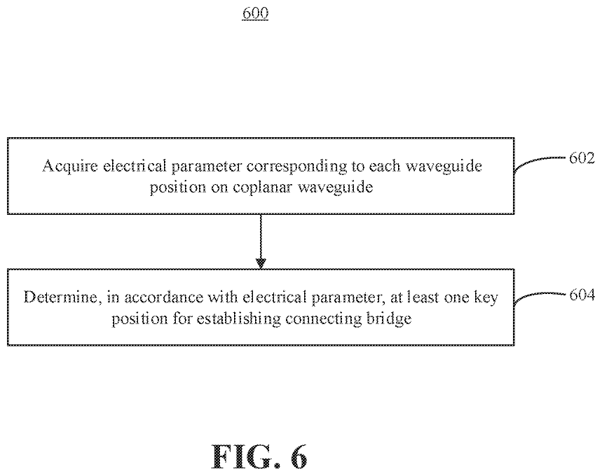

FIG. 6 is a flowchart of an example method 600 for determining at least one key position for establishing a connecting bridge on a coplanar waveguide, consistent with some embodiments of the present disclosure. For example, method 600 can be performed to implement step 502 in FIG. 5. Method 600 can be executed by a quantum chip preparation device. It is understandable that the preparation device can be implemented as software or a combination of software and hardware.

At step 602, an electrical parameter corresponding to each waveguide position on the coplanar waveguide can be acquired. At step 604, at least one key position for establishing the connecting bridge can be determined in accordance with the electrical parameter.

In some embodiments, at step 602, after the coplanar waveguide is acquired, the coplanar waveguide can be analyzed to acquire the electrical parameter corresponding to each waveguide position on the coplanar waveguide. By way of example, the electrical parameter can include at least one of electromagnetic field energy density, capacitance, or inductance. In some embodiments, each waveguide position on the coplanar waveguide can be detected by a preset sensing device to acquire the electrical parameter corresponding to each waveguide position on the coplanar waveguide. After the electrical parameter is acquired, the electrical parameter can be analyzed to determine at least one key position for establishing a connecting bridge at step 604.

In some embodiments, at step 604, determining at least one key position for establishing the connecting bridge in accordance with the electrical parameter can include analyzing and comparing the electrical parameter with a parameter threshold; and when the electrical parameter is greater than or equal to the parameter threshold, determining a waveguide position corresponding to the electrical parameter as a key position. For example, the parameter threshold for determining the key position can be pre-configured. Different parameter thresholds can correspond to different electrical parameters. By way of example, when the electrical parameter is the electromagnetic field energy density, the parameter threshold can be an electromagnetic field energy density threshold. When the electrical parameter is the capacitance, the parameter threshold can be a capacitance threshold. When the electrical parameter is the inductance, the parameter threshold can be an inductance threshold.

After the electrical parameter is acquired, the electrical parameter can be analyzed and compared with the parameter threshold. When the electrical parameter is greater than or equal to the parameter threshold, it indicates that the electromagnetic field energy density, capacitance, or inductance corresponding to the electrical parameter is strong, and then a waveguide position corresponding to the electrical parameter can be determined as a key position. When the electrical parameter is smaller than the parameter threshold, a waveguide position corresponding to the electrical parameter can be determined as a non-key position, thus effectively ensuring the accuracy and reliability of determining the key position.

Referring back to step 504 of FIG. 5, in some embodiments, after the at least one key position is acquired, the at least one connecting bridge can be established at the at least one key position by using the bonding machine. It is understandable that the number of the connecting bridges can be greater than or equal to the number of the key positions.

In the technical solutions provided in the present disclosure, by determining at least one key position for establishing the connecting bridge on the coplanar waveguide, and then establishing at least one connecting bridge at the at least one key position by using the bonding machine, not only the establishment of the connecting bridge on the coplanar waveguide by using the bonding machine can be implemented, but also the quality and efficiency of establishing the connecting bridge can be improved. By doing so, the influence of the chip electromagnetic resonance on the quantum chip can be reduced or avoided, and the performance of the quantum chip can be further improved.

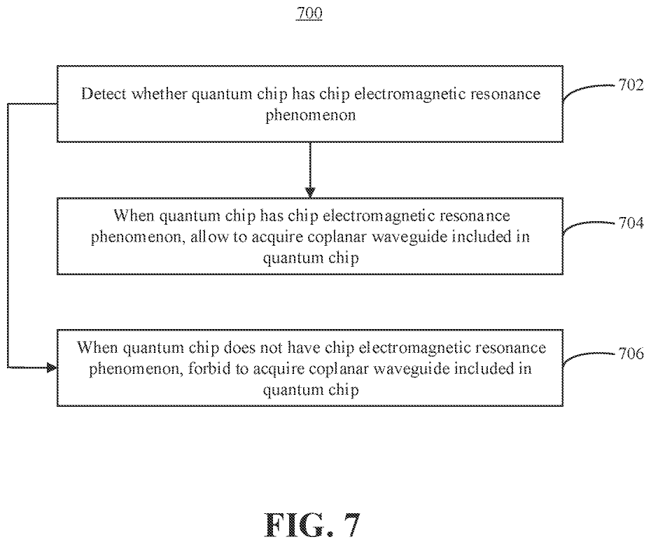

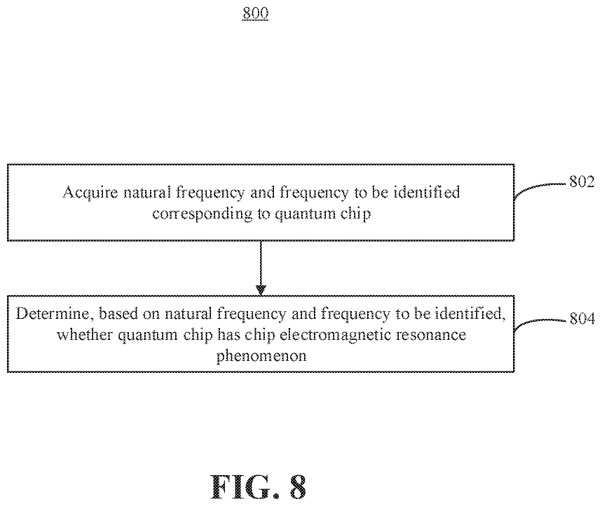

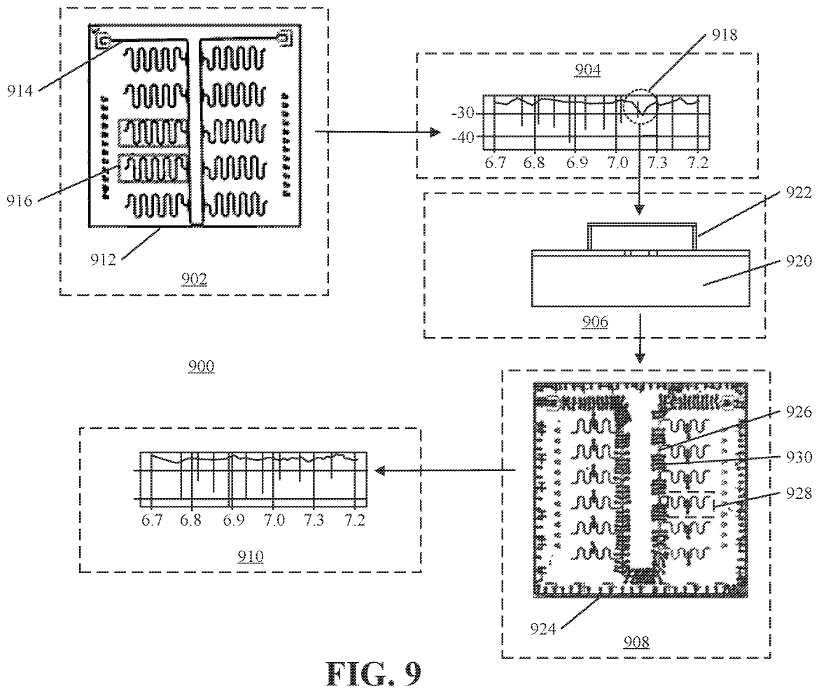

FIG. 7 is a flowchart of an example method 700 for quantum chip preparation, consistent with some embodiments of the present disclosure. FIG. 8 is a flowchart of an example method for detecting whether a quantum chip has a chip electromagnetic resonance phenomenon, consistent with some embodiments of the present disclosure. FIG. 9 is a schematic scenario diagram illustrating an example method 900 for quantum chip preparation, consistent with some embodiments of the present disclosure. Methods 700-900 can be executed by a quantum chip preparation device. It is understandable that the preparation device can be implemented as software or a combination of software and hardware.

With reference to FIG. 7, at step 702, it is detected whether the quantum chip has a chip electromagnetic resonance phenomenon. To ensure the performance and quality of the quantum chip, after the quantum chip is acquired, a chip electromagnetic resonance detection operation can be performed on the quantum chip. For example, it can be detected whether the quantum chip has the chip electromagnetic resonance phenomenon.

By way of example, with reference to FIG. 8, detecting whether the quantum chip has a chip electromagnetic resonance phenomenon at step 702 can include the following steps. At step 802, a natural frequency and a frequency to be identified corresponding to the quantum chip can be acquired. At step 804, it is determined, based on the natural frequency and the frequency to be identified, whether the quantum chip has a chip electromagnetic resonance phenomenon.

For example, at step 802, after the quantum chip is acquired, the quantum chip can be analyzed to acquire the natural frequency and the frequency to be identified corresponding to the quantum chip. The natural frequency can correspond to inherent features of the quantum chip (e.g., quality, shape, material, or design circuit). After the natural features of the quantum chip are determined, the natural frequency of the quantum chip can be determined. The frequency to be identified can be related to a circuit structure of the quantum chip and information of an environment in which the quantum chip is located. In addition, a direct test can be performed by using a microwave device to determine the natural frequency and the frequency to be identified.

After the natural frequency and the frequency to be identified are acquired, at step 804, the natural frequency and the frequency to be identified can be analyzed to determine whether the quantum chip has a chip electromagnetic resonance phenomenon. For example, step 804 can include: when the frequency to be identified is the same as the natural frequency, determining that the quantum chip does not have a chip electromagnetic resonance phenomenon; or, when the frequency to be identified is different from the natural frequency, determining that the quantum chip has a chip electromagnetic resonance phenomenon.

When the frequency to be identified is the same as the natural frequency, it can be determined that the quantum chip does not have a chip electromagnetic resonance phenomenon at this time. When the frequency to be identified is different from the natural frequency, it can be determined that the quantum chip has a chip electromagnetic resonance phenomenon. By doing so, the accuracy and reliability of detecting whether the quantum chip has a chip electromagnetic resonance phenomenon can be effectively ensured.

Referring back to FIG. 7, at step 704, when the quantum chip has a chip electromagnetic resonance phenomenon, it is allowed to acquire a coplanar waveguide included in the quantum chip. By doing so, a connecting bridge on the coplanar waveguide can be established by using the bonding machine. The connecting bridge can be configured to connect a first reference ground and a second reference ground on two sides of the coplanar waveguide, to change the chip electromagnetic resonance frequency and reduce the influence of the chip electromagnetic resonance on the quantum chip.

At step 706, when the quantum chip does not have a chip electromagnetic resonance phenomenon, it is forbidden to acquire a coplanar waveguide included in the quantum chip. When the quantum chip does not have a chip electromagnetic resonance phenomenon, the quantum chip at this time does not have the influence of the chip electromagnetic resonance. Therefore, it can be forbidden to acquire the coplanar waveguide included in the quantum chip, and the preparation operation of the quantum chip can be directly completed.

With reference to FIG. 9, in a specific application, method 900 provides a technical solution for eliminating or reducing the chip electromagnetic resonance of a superconducting quantum chip by establishing a bonding aluminum wire connecting bridge. For example, method 900 can include connecting a first reference ground and a second reference ground on two sides of a coplanar waveguide by using an established aluminum wire connecting bridge. By doing so, the influence of the chip electromagnetic resonance on the quantum chip can be effectively reduced.

With reference to FIG. 9, at step 902, a quantum chip 912 is acquired. Quantum chip 912 includes a transmission line 914 and a resonant cavity 916. Transmission line 914 can be configured to transmit a signal, and resonant cavity 916 can be coupled to transmission line 914 and configured to implement a regulation operation on an operating state of qubits on the quantum chip. For example, the regulation operation can include adjustment, configuration, reading, or controlling. Transmission line 914 and resonant cavity 916 can be both composed of a coplanar waveguide.

At step 904, a chip electromagnetic resonance detection operation can be performed on quantum chip 912. At step 906, when quantum chip 912 has a chip electromagnetic resonance phenomenon (e.g., a dip in a curve that represents detected chip electromagnetic resonance values, such as dip 918 in dotted circle at step 904), a coplanar waveguide 920 included in quantum chip 912 can be acquired, and a connecting bridge 922 can be established on coplanar waveguide 920 by using a bonding machine (not shown in FIG. 9). Connecting bridge 922 can be configured to connect a first reference ground and a second reference ground on two sides of coplanar waveguide 920 to change the chip electromagnetic resonance frequency and reduce the influence of the chip electromagnetic resonance on quantum chip 912.

In some embodiments, after the detection operation is performed on quantum chip 912 at step 904, a mapping relationship between a working frequency and a signal strength can be acquired (e.g., represented as a curve), and it can be identified whether quantum chip 912 has a chip electromagnetic resonance phenomenon by using corresponding relationships between different working frequencies and different signal strengths. When quantum chip 912 has a chip electromagnetic resonance phenomenon (e.g., the signal strength oscillates when the working frequency is at about 7.05 GHz), it can be determined that quantum chip 912 has a chip electromagnetic resonance.

When it is determined that quantum chip 912 has a chip electromagnetic resonance phenomenon, coplanar waveguide 920 included in quantum chip 912 can be acquired. In some embodiments, the number of coplanar waveguide 920 can be one or more. After coplanar waveguide 920 is acquired, an aluminum wire connecting bridge (e.g., implemented as connecting bridge 922) can be established on coplanar waveguide 920 by using the bonding machine. The aluminum wire connecting bridge can be configured to connect the first reference ground and the second reference ground on two sides of coplanar waveguide 920, thereby changing the chip electromagnetic resonance frequency and reducing the influence of the chip electromagnetic resonance on quantum chip 912.

In some embodiments, the number of aluminum wire connecting bridges can be at least one, and a distance between adjacent aluminum wire connecting bridges can be a value not exceeding 200 microns. In some embodiments, a greater density of the aluminum wire connecting bridges can reduce the influence of the chip electromagnetic resonance on quantum chip 912 more effectively.

At step 908, after connecting bridge 922 is established on coplanar waveguide 920 by using the bonding machine, a target quantum chip 924 corresponding to quantum chip 912 can be obtained. Target quantum chip 924 can include a transmission line 926 configured to transmit a signal and a resonant cavity 928 coupled to transmission line 926 and configured to regulate an operating state of qubits on target quantum chip 924. The operating state of target quantum chip 924 can include a preset 0 state and a preset 1 state. Transmission line 926 and resonant cavity 928 can be both composed of a coplanar waveguide. The coplanar waveguide can be provided with one or more connecting bridges 930 (such as the connecting bridges shown in FIG. 9), and connecting bridges 930 can be configured to connect a first reference ground and a second reference ground on two sides of the coplanar waveguide to change the chip electromagnetic resonance frequency and reduce the influence of the chip electromagnetic resonance on the target quantum chip.

In some embodiments, transmission line 926 can include multiple key positions. The number of key positions can be related to the scale and structural design of quantum chip 912. A larger quantum chip can have a larger quantity of key positions. For example, transmission line 926 can include two, three, four, or five key positions. In some cases, one resonant cavity can correspond to at least one key position. When the number of the key positions is one, the key position can be located in the middle of the resonant cavity. Therefore, multiple connecting bridges (e.g., connecting bridges 930) can be established on transmission line 926 and at least one connecting bridge can be established in the resonant cavity.

At step 910, a chip electromagnetic resonance detection operation can be performed on target quantum chip 924. After the detection operation is performed on target quantum chip 924, a mapping relationship between a working frequency and a signal strength can be acquired (e.g., represented as a curve), and it can be identified whether target quantum chip 924 has a chip electromagnetic resonance phenomenon by using corresponding relationships between different working frequencies and different signal strengths. For example, the signal intensities corresponding to different frequencies can present no additional chip electromagnetic resonance beyond the design. In such cases, it can be determined that quantum chip 912 does not have a chip electromagnetic resonance, which effectively reduces or avoids the influence of the chip electromagnetic resonance on quantum chip 912.

In some embodiments, the manufacturing of the aluminum wire connecting bridge by the bonding machine can be simple, reliable, and fast. The size of the aluminum wire connecting bridge can be much larger than the micro-nano processed connecting bridge, thus reducing the difficulty of establishing the aluminum wire connecting bridge. In addition, the quantum chip does not need to be in contact with any chemical solvent and photoresist, which can effectively avoid pollution and damage to the quantum chip. Also, by building the connecting bridge on the planar waveguide, the influence of the chip electromagnetic resonance on the chip can be eliminated or reduced, thereby the performance of the quantum chip can be ensured and improved. Further, the stability and reliability of the preparation of the quantum chip can be improved, which can further increase beneficiary for market promotion and industrial application.

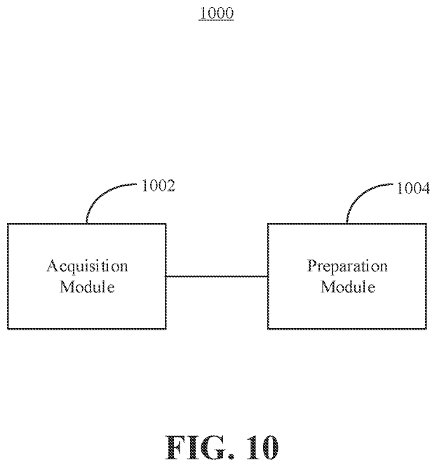

FIG. 10 is a schematic structural diagram illustrating a quantum chip preparation apparatus 1000, consistent with some embodiments of the present disclosure. In some embodiments, apparatus 1000 can perform the methods (e.g., methods 100, 400, 500, 600 700, 800, or 900) described in association with FIGS. 1-9. For parts, implementation processes, and technical effects that are not described in detail in FIG. 10, reference can be made to the related description of the embodiments described in association with FIGS. 1-9.

Apparatus 1000 includes an acquisition module 1002 that is configured to acquire a coplanar waveguide comprised in a quantum chip. Apparatus 1000 further includes a preparation module 1004 is configured to establish a connecting bridge on the coplanar waveguide by using a bonding machine. The connecting bridge can be configured to connect a first reference ground and a second reference ground on two sides of the coplanar waveguide to change the chip electromagnetic resonance frequency. It is understandable that acquisition module 1002 and preparation module 1004 can be implemented as software or a combination of software and hardware.

In some embodiments, when the coplanar waveguide included in the quantum chip is acquired, acquisition module 1002 can be configured to perform: acquiring a layout structure of the quantum chip, and determining a coplanar waveguide included in the quantum chip based on the layout structure. In some embodiments, when a coplanar waveguide included in the quantum chip is determined based on the layout structure, acquisition module 1002 can be configured to perform: analyzing the layout structure by using a machine learning model to determine a coplanar waveguide included in the quantum chip. The machine learning model can be trained to determine a coplanar waveguide included in a quantum chip based on a layout structure.

In some embodiments, when a connecting bridge is established on a coplanar waveguide by using a bonding machine, preparation module 1004 can be configured to perform: determining at least one key position for establishing a connecting bridge on the coplanar waveguide and establishing at least one connecting bridge at the at least one key position by using the bonding machine. In some embodiments, when at least one key position for establishing a connecting bridge is determined on the coplanar waveguide, preparation module 1004 can be configured to perform: acquiring an electrical parameter corresponding to each waveguide position on the coplanar waveguide and determining at least one key position for establishing the connecting bridge in accordance with the electrical parameter.

In some embodiments, when at least one key position for establishing the connecting bridge is determined in accordance with the electrical parameter, preparation module 1004 can be configured to perform: analyzing and comparing the electrical parameter with a parameter threshold, and when the electrical parameter is greater than or equal to the parameter threshold, determining a waveguide position corresponding to the electrical parameter as a key position.

In some embodiments, the electrical parameter can include at least one of electromagnetic field energy density, capacitance, or inductance. In some embodiments, the number of the connecting bridges can be at least one, and a distance between two adjacent connecting bridges can be smaller than or equal to a preset value. In some embodiments, density information of the connecting bridge can be greater than or equal to a preset density threshold, and the preset density threshold can be related to the space occupied by the quantum chip, the performance of the bonding machine, or the wire diameter.

In some embodiments, the connecting bridge can be composed of a superconducting wire. For example, the superconducting wire can include an aluminum wire. In some embodiments, an arrangement direction of the connecting bridge can be perpendicular to a signal transmission direction of the coplanar waveguide.

In some embodiments, preparation module 1004 can be configured to perform detecting whether the quantum chip has a chip electromagnetic resonance phenomenon. When the quantum chip has a chip electromagnetic resonance phenomenon, preparation module 1004 can be configured to perform allowing to acquire the coplanar waveguide included in the quantum chip. When the quantum chip does not have a chip electromagnetic resonance phenomenon, preparation module 1004 can be configured to perform forbidding to acquire the coplanar waveguide included in the quantum chip.

In some embodiments, when it is detected whether the quantum chip has a chip electromagnetic resonance phenomenon, preparation module 1004 can be configured to perform: acquiring a natural frequency and a frequency to be identified corresponding to the quantum chip, and determining, based on the natural frequency and the frequency to be identified, whether the quantum chip has a chip electromagnetic resonance phenomenon.

In some embodiments, the frequency to be identified can be related to a circuit structure of the quantum chip and information of an environment in which the quantum chip is located. In some embodiments, when it is determined, based on the natural frequency and the frequency to be identified, whether the quantum chip has a chip electromagnetic resonance phenomenon, preparation module 1004 can be configured to perform determining that the quantum chip does not have a chip electromagnetic resonance phenomenon when the frequency to be identified is the same as the natural frequency. When the frequency to be identified is different from the natural frequency, preparation module 1004 can be configured to perform determining that the quantum chip has a chip electromagnetic resonance phenomenon.

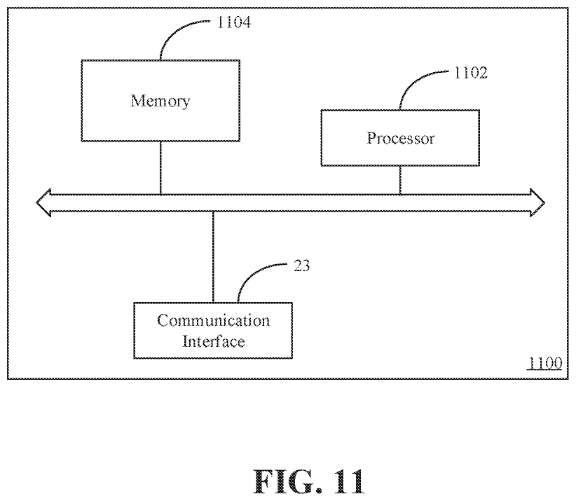

FIG. 11 is a schematic structural diagram illustrating a quantum chip preparation device 1100, consistent with some embodiments of the present disclosure. In some embodiments, device 1100 can perform the methods (e.g., methods 100, 400, 500, 600 700, 800, or 900) described in association with FIGS. 1-10. For parts, implementation processes, and technical effects that are not described in detail in FIG. 11, reference can be made to the related description of the embodiments described in association with FIGS. 1-10.

Device 1100 includes a memory 1104 and processor 1102. Memory 1104 can be used to store one or more computer instructions. The one or more computer instructions, when executed by processor 1102, can implement the methods (e.g., methods 100, 400, 500, 600 700, 800, or 900) described in association with FIGS. 1-10. Device 1100 can also include a communication interface 1106 for device 1100 to communicate with another device or via a communication network (not shown in FIG. 11). In some embodiments, a quantum chip can be provided by using device 1100 that implements the methods (e.g., methods 100, 400, 500, 600 700, 800, or 900) described in association with FIGS. 1-10.

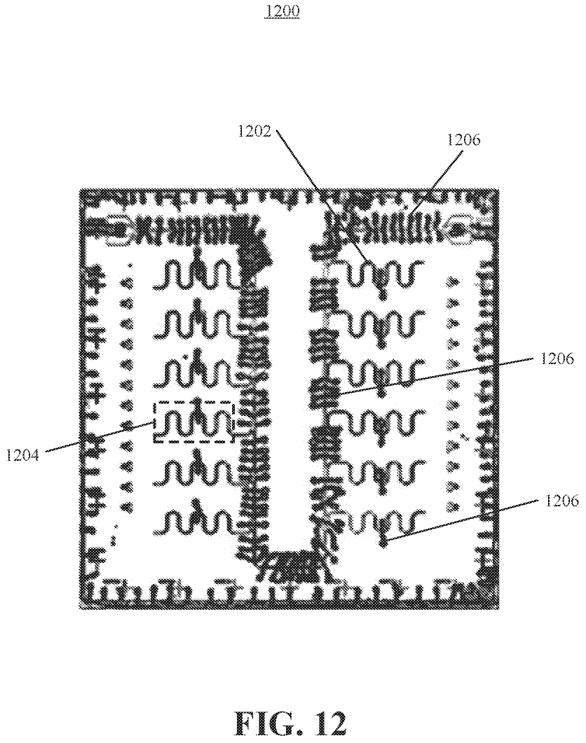

FIG. 12 is a schematic structural diagram illustrating an example quantum chip 1200, consistent with some embodiments of the present disclosure. The influence of the chip electromagnetic resonance on quantum chip 1200 can be small. In some embodiments, quantum chip 1200 can perform the methods (e.g., methods 100, 400, 500, 600 700, 800, or 900) described in association with FIGS. 1-11. For parts, implementation processes, and technical effects that are not described in detail in FIG. 12, reference can be made to the related description of the embodiments described in association with FIGS. 1-11.

Quantum chip 1200 can include transmission line 1202 configured to realize signal transmission. Quantum chip 1200 can also include a resonant cavity 1204 coupled to transmission line 1202 and configured to regulate an operating state of qubits on quantum chip 1200. Transmission line 1202 and resonant cavity 1204 can be both composed of a coplanar waveguide. The coplanar waveguide can be provided with a connecting bridge 1206. For example, connecting bridge 1206 can be established on the coplanar waveguide by using a bonding machine. Connecting bridge 1206 can be configured to connect a first reference ground and a second reference ground on two sides of the coplanar waveguide to change the chip electromagnetic resonance frequency.

In some embodiments, quantum chip 1200 can also include a Josephson junction (not shown in FIG. 12), and the Josephson junction can be composed of a superconductor, an insulator, or a superconductor. The Josephson junction can be coupled to transmission line 1202 and resonant cavity 1204, in which transmission line 1202 and resonant cavity 1204 can be configured for signal transmission for the Josephson junction.

In some embodiments, the number of connecting bridge 1206 can be at least one. When the number of connecting bridge 1206 is more than one, a distance between two adjacent connecting bridges can be smaller than or equal to a preset value.

In some embodiments, density information of connecting bridge 1206 can be greater than or equal to a preset density threshold. The preset density threshold can be related to the space occupied by quantum chip 1200, the performance of the bonding machine, and the wire diameter.

In some embodiments, connecting bridge 1206 can be composed of a superconducting wire. In some embodiments, the superconducting wire can include an aluminum wire. In some embodiments, an arrangement direction of connecting bridge 1206 can be perpendicular to a signal transmission direction of the coplanar waveguide.

Consistent with some embodiments of this disclosure, a non-transitory computer storage medium for storing computer software instructions used by an electronic device can be provided. The non-transitory computer storage medium can include programs for performing the methods (e.g., methods 100, 400, 500, 600 700, 800, or 900) described in association with FIGS. 1-12.

The embodiments can further be described using the following clauses:

1. A method for quantum chip preparation, comprising: acquiring a coplanar waveguide in a quantum chip; and establishing a connecting bridge on the coplanar waveguide using a bonding machine, wherein the connecting bridge is configured to connect a first reference ground and a second reference ground located on two sides of the coplanar waveguide to change the chip electromagnetic resonance frequency.

2. The method of clause 1, wherein acquiring the coplanar waveguide in the quantum chip comprises: acquiring a layout structure of the quantum chip; and determining the coplanar waveguide in the quantum chip based on the layout structure.

3. The method of clause 2, wherein determining the coplanar waveguide in the quantum chip based on the layout structure comprises: analyzing the layout structure using a machine learning model to determine the coplanar waveguide in the quantum chip, wherein the machine learning model is trained to determine a particular coplanar waveguide in a particular quantum chip based on a particular layout structure.

4. The method of clause 1, wherein establishing the connecting bridge on the coplanar waveguide using the bonding machine comprises: determining at least one key position for establishing the connecting bridge on the coplanar waveguide; and establishing at least one connecting bridge at the at least one key position using the bonding machine.

5. The method of clause 4, wherein determining the at least one key position for establishing the connecting bridge on the coplanar waveguide comprises: acquiring an electrical parameter corresponding to a waveguide position on the coplanar waveguide; and determining, based on the electrical parameter, the at least one key position for establishing the connecting bridge.

6. The method of clause 5, wherein determining, based on the electrical parameter, the at least one key position for establishing the connecting bridge comprises: analyzing and comparing the electrical parameter with a parameter threshold; and determining the waveguide position corresponding to the electrical parameter as the key position when the electrical parameter is greater than or equal to the parameter threshold.

7. The method of clause 5, wherein the electrical parameter comprises at least one of electromagnetic field energy density, capacitance, or inductance.

8. The method of any of clauses 1-7, wherein the number of the connecting bridges is at least one, and a distance between two adjacent connecting bridges is smaller than or equal to a preset value when the number of the connecting bridges is at least two.

9. The method of clause 8, wherein density information of the connecting bridge is greater than or equal to a preset density threshold, and the preset density threshold is related to at least one of a space occupied by the quantum chip, performance of the bonding machine, or a wire diameter.

10. The method of any of clauses 1-7, wherein the connecting bridge is composed of a superconducting wire.

11. The method of clause 10, wherein the superconducting wire comprises an aluminum wire.

12. The method of any of clauses 1-7, wherein an arrangement direction of the connecting bridge is perpendicular to a signal transmission direction of the coplanar waveguide.

13. The method of any of clauses 1-7, further comprising: detecting whether the quantum chip has a chip electromagnetic resonance phenomenon; in response to the quantum chip having a chip electromagnetic resonance phenomenon, allowing to acquire the coplanar waveguide in the quantum chip; or in response to the quantum chip not having the chip electromagnetic resonance phenomenon, forbidding to acquire the coplanar waveguide comprised in the quantum chip.

14. The method of clause 13, wherein detecting whether the quantum chip has the chip electromagnetic resonance phenomenon comprises: acquiring a natural frequency and a frequency to be identified corresponding to the quantum chip; and determining, based on the natural frequency and the frequency to be identified, whether the quantum chip has a chip electromagnetic resonance phenomenon.

15. The method of clause 14, wherein the frequency to be identified is related to a circuit structure of the quantum chip and information of an environment in which the quantum chip is located.

16. The method of clause 14, wherein determining, based on the natural frequency and the frequency to be identified, whether the quantum chip has the chip electromagnetic resonance phenomenon comprises: when the frequency to be identified is the same as the natural frequency, determining that there is no chip electromagnetic resonance phenomenon in the quantum chip; and when the frequency to be identified is different from the natural frequency, determining that the quantum chip has a chip electromagnetic resonance phenomenon.

17. An apparatus for quantum chip preparation, comprising: an acquisition module configured to acquire a coplanar waveguide in a quantum chip; and a preparation module configured to establish a connecting bridge on the coplanar waveguide using a bonding machine, wherein the connecting bridge is configured to connect a first reference ground and a second reference ground located on two sides of the coplanar waveguide to change the chip electromagnetic resonance frequency.

18. An apparatus for inductance element preparation, comprising: a memory configured to store a set of instructions; and one or more processors communicatively coupled to the memory and configured to execute the set of instructions to cause the apparatus to perform the method of any of clauses 1-16.

19. A quantum chip, wherein the quantum chip is prepared by the method of any of clauses 1-16.

20. A quantum chip, comprising: a transmission line configured for signal transmission; and a resonant cavity coupled to the transmission line and configured to regulate an operating state of qubits on the quantum chip, wherein the transmission line and the resonant cavity are both composed of a coplanar waveguide, the coplanar waveguide is provided with a connecting bridge, and the connecting bridge is configured to connect a first reference ground and a second reference ground on two sides of the coplanar waveguide to change the chip electromagnetic resonance frequency.

21. The quantum chip of clause 20, wherein the number of the connecting bridges is at least one, and a distance between two adjacent connecting bridges is smaller than or equal to a preset value when the number of the connecting bridges is at least two.

22. The quantum chip of clause 21, wherein density information of the connecting bridge is greater than or equal to a preset density threshold, and the preset density threshold is related to a space occupied by the quantum chip, performance of a bonding machine, and a wire diameter.

23. The quantum chip of any of clauses 20-22, wherein the connecting bridge is composed of a superconducting wire.

24. The quantum chip of clause 23, wherein the superconducting wire comprises an aluminum wire.

25. The quantum chip of any of clauses 20-22, wherein an arrangement direction of the connecting bridge is perpendicular to a signal transmission direction of the coplanar waveguide.

It should be noted that the example apparatuses and devices described herein are only schematic, where the units described as separate components can or cannot be physically separated, and the components displayed as units can or cannot be physical units (e.g., can be located in one place, or can be distributed to a plurality of network units). Part or all of the modules can be selected in accordance with actual needs to achieve the purpose of the solution of the present embodiment. Those of ordinary skill in the art can understand and implement the solution of the present embodiment without creative effort.

From the description of the above implementations, those skilled in the art can clearly understand that the various implementations can be implemented by means of software plus a necessary hardware platform, and can also be implemented by a combination of hardware and software. Based on such understanding, the above technical solution essentially or the part contributing to the prior art can be embodied in the form of a computer product. The present disclosure can be in the form of a computer program product implemented on one or more computer-usable storage media (including, but not limited to, a magnetic disk memory, a CD-ROM, an optical memory, and the like) including computer usable program code.

The present disclosure is described with reference to flowcharts and/or block diagrams of methods, devices, systems, and computer program products in accordance with embodiments of the present disclosure. It should be understood that each flow and/or block in the flowcharts and/or block diagrams and a combination of flows and/or blocks in the flowcharts and/or block diagrams can be implemented by computer program instructions. These computer program instructions can be provided to a processor of a general-purpose computer, a special-purpose computer, an embedded processor, or another programmable device to produce a machine, so that the instructions executed by the processor of the computer or another programmable device produce an apparatus for realizing the functions specified in one or more flows of the flowcharts and/or one or more blocks of the block diagrams.

These computer program instructions can also be stored in a non-transitory computer-readable memory that can direct a computer or another programmable device to work in a specific manner, so that the instructions stored in this computer-readable memory produce an article of manufacture including an instruction apparatus which implements the functions specified in one or more flows of the flowcharts and/or one or more blocks of the block diagrams.

These computer program instructions can also be loaded onto a computer or another programmable device, so that a series of operation steps are performed on the computer or another programmable device to produce computer-implemented processing, so that the instructions executed on the computer or another programmable device provide steps for implementing the functions specified in one or more flows of the flowcharts and/or one or more blocks of the block diagrams.

The non-transitory computer-readable medium includes permanent and non-permanent, removable and non-removable media, which can implement storage of information by using any method or technology. The information can be computer-readable instructions, data patterns, program modules, or other data. Examples of computer storage media include, but are not limited to, a phase change memory (PRAM), a static random access memory (SRAM), a dynamic random access memory (DRAM), other type of random access memory (RAM), a read-only memory (ROM), an electrically erasable programmable read-only memory (EEPROM), a flash memory or other memory technologies, a compact disc read-only memory (CD-ROM), a digital versatile disc (DVD) or other optical storage, a cassette magnetic tape, tape and disk storage or other magnetic storage devices, or any other non-transmission media, which can be configured to store information accessible by a computing device. As defined herein, the computer-readable medium does not include computer-readable transitory media, such as a modulated data signal and a carrier.

In a typical configuration, the computing device includes one or more processors (CPUs), an input/output interface, a network interface, and a memory. The memory can include a volatile memory, a random access memory (RAM), and/or a non-volatile memory in computer-readable media, e.g., a read-only memory (ROM) or a flash RAM. The memory is an example of the computer-readable medium.

Finally, it should be noted that the above embodiments are only used to illustrate the technical solutions of the present disclosure, and are not intended to limit the present disclosure. Although the present disclosure has been described in detail with reference to the foregoing embodiments, those of ordinary skill in the art should understand that the technical solutions recorded in the foregoing various embodiments can still be modified, or some of the technical features thereof can be equivalently replaced. These modifications or replacements do not cause the essence of the corresponding technical solutions to deviate from the spirit and scope of the technical solutions of the embodiments of the present disclosure.

What is claimed is:

1. A method for quantum chip preparation, comprising:
acquiring a coplanar waveguide in a quantum chip; and
establishing a connecting bridge on the coplanar waveguide using a bonding machine, wherein the connecting bridge is configured to connect a first reference ground and a second reference ground located on two sides of the coplanar waveguide to change the chip electromagnetic resonance frequency.

2. The method of claim 1, wherein acquiring the coplanar waveguide in the quantum chip comprises:
acquiring a layout structure of the quantum chip; and
determining the coplanar waveguide in the quantum chip based on the layout structure.

3. The method of claim 2, wherein determining the coplanar waveguide in the quantum chip based on the layout structure comprises:
analyzing the layout structure using a machine learning model to determine the coplanar waveguide in the quantum chip, wherein the machine learning model is trained to determine a particular coplanar waveguide in a particular quantum chip based on a particular layout structure.

4. The method of claim 1, wherein establishing the connecting bridge on the coplanar waveguide using the bonding machine comprises:
determining at least one key position for establishing the connecting bridge on the coplanar waveguide; and
establishing at least one connecting bridge at the at least one key position using the bonding machine.

5. The method of claim 4, wherein determining the at least one key position for establishing the connecting bridge on the coplanar waveguide comprises:
acquiring an electrical parameter corresponding to a waveguide position on the coplanar waveguide; and
determining, based on the electrical parameter, the at least one key position for establishing the connecting bridge.

6. The method of claim 5, wherein determining, based on the electrical parameter, the at least one key position for establishing the connecting bridge comprises:
analyzing and comparing the electrical parameter with a parameter threshold; and
determining the waveguide position corresponding to the electrical parameter as the key position when the electrical parameter is greater than or equal to the parameter threshold.

7. The method of claim 5, wherein the electrical parameter comprises at least one of electromagnetic field energy density, capacitance, or inductance.

8. The method of claim 1, wherein the number of the connecting bridges is at least one, and a distance between two adjacent connecting bridges is smaller than or equal to a preset value when the number of the connecting bridges is at least two.

9. The method of claim 8, wherein density information of the connecting bridge is greater than or equal to a preset density threshold, and the preset density threshold is related to at least one of a space occupied by the quantum chip, performance of the bonding machine, or a wire diameter.

10. The method of claim 1, wherein the connecting bridge is composed of a superconducting wire.

11. The method of claim 10, wherein the superconducting wire comprises an aluminum wire.

12. The method of claim 1, wherein an arrangement direction of the connecting bridge is perpendicular to a signal transmission direction of the coplanar waveguide.

13. The method of claim 1, further comprising:
detecting whether the quantum chip has a chip electromagnetic resonance phenomenon;
in response to the quantum chip having a chip electromagnetic resonance phenomenon, allowing to acquire the coplanar waveguide in the quantum chip; or
in response to the quantum chip not having the chip electromagnetic resonance phenomenon, forbidding to acquire the coplanar waveguide comprised in the quantum chip.

14. The method of claim 13, wherein detecting whether the quantum chip has the chip electromagnetic resonance phenomenon comprises:
acquiring a natural frequency and a frequency to be identified corresponding to the quantum chip; and
determining, based on the natural frequency and the frequency to be identified, whether the quantum chip has a chip electromagnetic resonance phenomenon.

15. The method of claim 14, wherein the frequency to be identified is related to a circuit structure of the quantum chip and information of an environment in which the quantum chip is located.

16. The method of claim 14, wherein determining, based on the natural frequency and the frequency to be identified, whether the quantum chip has the chip electromagnetic resonance phenomenon comprises:
when the frequency to be identified is the same as the natural frequency, determining that there is no chip electromagnetic resonance phenomenon in the quantum chip; or
when the frequency to be identified is different from the natural frequency, determining that the quantum chip has a chip electromagnetic resonance phenomenon.

17. A quantum chip, comprising:
a transmission line configured for signal transmission; and
a resonant cavity coupled to the transmission line and configured to regulate an operating state of qubits on the quantum chip,
wherein the transmission line and the resonant cavity are both composed of a coplanar waveguide, the coplanar waveguide is provided with a connecting bridge, and the connecting bridge is configured to connect a first reference ground and a second reference ground on two sides of the coplanar waveguide to change the chip electromagnetic resonance frequency.

18. The quantum chip of claim 17, wherein the number of the connecting bridges is at least one, and a distance between two adjacent connecting bridges is smaller than or equal to a preset value when the number of the connecting bridges is at least two.

19. The quantum chip of claim 18, wherein density information of the connecting bridge is greater than or equal to a preset density threshold, and the preset density threshold is related to a space occupied by the quantum chip, performance of a bonding machine, and a wire diameter.

20. The quantum chip of claim 17, wherein the connecting bridge is composed of a superconducting wire, and an arrangement direction of the connecting bridge is perpendicular to a signal transmission direction of the coplanar waveguide.
